(19) United States
(12) Patent Application Publication
(10) Pub. No.: US 2011/0254808 A1
(43) Pub. Date: Oct. 20, 2011

(54) REFLECTIVE TOUCH DISPLAY PANEL AND MANUFACTURING METHOD THEREOF

(75) Inventors: Hsiang-Lin LIN, Hsin-Chu (TW); Chih-Jen HU, Hsin-Chu (TW); Wei-Ming HUANG, Hsin-Chu (TW)

(73) Assignee: AU OPTRONICS CORPORATION, Hsin-Chu (TW)

(21) Appl. No.: 12/795,670

(22) Filed: Jun. 8, 2010

(30) Foreign Application Priority Data
Apr. 20, 2010 (TW) 99112375

(51) Int. Cl. G06F 3/042; H01L 31/18; H01L 33/00

(52) U.S. Cl. 345/175; 438/25; 257/E33.076

(57) ABSTRACT

A reflective touch display panel and a manufacturing method thereof are provided. An incident light enters the display panel through a front substrate thereof. A plurality of pixel structures and a plurality of light sensing devices are disposed on an inner surface of the front substrate. The light sensing device includes a light sensing transistor having a transparent gate electrode. The manufacturing method for the reflective touch display panel includes the following steps. A first patterned transparent conductive layer, including the transparent gate electrode and a capacitance lower electrode, is formed on the front substrate. A first patterned conductive layer, a dielectric layer, a patterned semi-conductive layer, a second patterned conductive layer and a second patterned transparent conductive layer are sequentially formed on the front substrate to respectively form the light sensing device and the pixel structure. A reflective material layer and a back substrate are. assembled on the front substrate to complete the reflective touch display panel.

### RELATED APPLICATIONS

This application claims priority to Taiwan Application Serial Number 99112375, filed Apr. 20, 2010, which is herein incorporated by reference.

### BACKGROUND

1. Technical Field

The present invention relates to a touch display panel and a manufacturing method thereof. More particularly, the present invention relates to a reflective touch display panel and a manufacturing method thereof.

2. Description of Related Art

Along with the advances of manufacturing techniques for display devices, earlier heavy weight and high power consumption cathode ray tube display devices have been replaced with modern thin display devices. The thin display devices are now the main stream and the first priority option for consumers. In recent years, the energy issues are brought forth frequently, and the market made a higher standard for power consumption of display devices. In response to the requirement for greener display devices on the market, the industry has devoted to developing thinner display devices with lower power consumption.

In comparison to the transmissive liquid crystal or plasma display device, the reflective electronic paper display device displays a picture by reflecting external light. Therefore the electronic paper display device needs no backlight modules, and its weight and thickness may be further reduced, as well as the power consumption. Further, in order to increase the usability, a touch electronic paper display device is developed. Generally, the touch electronic paper display device is accomplished by adhering a resistive touch film or a capacitive touch film on the electronic paper display device. This technique increases not only the overall cost of the display device: but also the complexity of the manufacturing process.

Further to solve the issues about cost and manufacturing process, an integrated touch electronic paper display device is developed, in which a light sensor is integrated in a known pixel structure. However, due to the reason that the light sensor is located beneath the display material layer, the external light has to penetrate through the display material layer before reaching the light sensor. In this case, the light sensor suffers from the problem of insufficient intensity of light, and the sensitivity of the sensor in the integrated touch electronic paper display device is lowered.. Therefore, the utility of touch operation is limited, and the quality of the product is affected accordingly.

### SUMMARY

A reflective touch display panel and a manufacturing method thereof are provided to solve the issue of lowering the sensitivity of the light sensing device.

According to one aspect of the invention, a reflective touch display panel is provided. The reflective touch display panel includes a front substrate, a plurality of pixel structures, a plurality of light sensing devices, a back substrate and a reflective material layer. The front substrate through which an incident light penetrates has an inner surface. The pixel structures are disposed on the inner surface of the front substrate. The light sensing devices are disposed on the inner surface of the front substrate. Each of the light sensing devices includes a light sensing transistor and a readout element electrically connected to the light sensing transistor. The light sensing transistor comprises a transparent gate electrode, a first gate dielectric layer, a first semiconductor layer, a first source electrode and a first drain electrode. The transparent gate electrode is disposed on the inner surface of the front substrate. The first gate dielectric layer and the first semiconductor layer are sequentially disposed on the transparent gate electrode. The first source electrode and the first drain electrode are respectively connected to two sides of the first semiconductor layer. The back substrate is disposed on one side of the front substrate in parallel. The reflective material layer is disposed between the front and the back substrates to reflect the incident light penetrating through the front substrate.

In one embodiment of the invention, each of the pixel structures includes a thin film transistor, a pixel electrode and a capacitor lower electrode. The thin film transistor includes a second gate electrode, a second gate dielectric layer, a second semiconductor layer, a second source electrode and a second drain electrode. The second gate electrode is disposed on the inner surface of the front substrate. The second gate dielectric layer and the second semiconductor layer are sequentially disposed on the second gate electrode. The second source electrode and the second drain electrode are respectively connected to two sides of the second semiconductor layer. The pixel electrode is electrically connected to the second source electrode. The capacitor lower electrode, which is made of a transparent material; is disposed on the inner surface of the front substrate. The capacitor lower electrode and the pixel electrode form a transparent storage capacitor.

In a further embodiment of the invention, each of the readout elements includes a third gate electrode, a third gate dielectric layer, a third semiconductor layer, a third source electrode and a third drain electrode. The third gate electrode is disposed on the inner surface of the front substrate. The third gate dielectric layer and the third semiconductor layer are sequentially disposed on the third gate electrode. The third source electrode and the third drain electrode are respectively connected to two sides of the third semiconductor layer.

In yet another embodiment of the invention, the reflective touch display panel further includes a plurality of scan lines, a plurality of data lines, a plurality of signal input lines and a plurality of signal output lines. Each of the scan is lines is electrically connected to the second gate electrode of the corresponding thin film transistor and the third gate electrode of the corresponding readout element. The data lines cross the scan lines, and each of the data lines is electrically connected to the second source electrode of the corresponding thin film transistor. The signal input lines are parallel to the scan lines, and each of the signal input lines is electrically connected to the first source electrode of the corresponding light sensing transistor. The signal output lines cross the signal input lines, and each of the signal output lines is electrically connected to the third drain electrode of the corresponding readout element.

According to another aspect of the invention, a manufacturing method of a reflective touch display panel is provided. The manufacturing method includes the following steps: forming a first patterned transparent conductive layer on a front substrate, in which the first patterned transparent conductive layer includes a transparent gate electrode for forming a light sensing device and a capacitor lower electrode for forming a transparent storage capacitor of a pixel structure; sequentially forming a first patterned conductive layer, a dielectric layer, a patterned semiconductor layer, a second patterned conductive layer and a second patterned transparent conductive layer on the front substrate for forming the light sensing device and the pixel structure; and assembling a reflective material layer and a back substrate on the front substrate in a manner that the reflective material layer is located between the front substrate and the back substrate.

In one embodiment of the invention, the step of sequentially forming the first patterned conductive layer, the dielectric layer, the patterned semiconductor layer, the second patterned conductive layer and the second patterned transparent conductive layer on the front substrate includes the following steps: sequentially forming the first patterned conductive layer, the dielectric layer, the patterned semiconductor layer and the second patterned conductive layer on the front substrate; forming a protective layer with a contact hole covering the front substrate; and forming the second patterned transparent conductive layer on the protective layer so that the second patterned transparent conductive layer is in electrical contact with the second patterned conductive layer through the contact hole.

In another embodiment of the invention, the step of sequentially forming the first patterned conductive layer, the dielectric layer, the patterned semiconductor layer, the second patterned conductive layer and the second patterned transparent conductive layer on the front substrate includes the following steps: forming the first patterned conductive layer that comprises a second gate electrode on the front substrate; forming the dielectric layer covering the second gate electrode, the transparent gate electrode and the capacitor lower electrode; forming the patterned semiconductor layer on the dielectric layer; forming the second patterned conductive layer that comprises a first source electrode, a first drain electrode, a second source electrode and a second drain electrode on the dielectric layer, in which the first source electrode, the first drain electrode and the transparent gate electrode form a light sensing transistor, and the second source electrode, the second drain electrode and the second gate electrode form a thin film transistor; forming the protective layer with the contact hole covering the light sensing device and the thin film transistor; and forming the second patterned transparent conductive layer on the protective layer such that the second patterned transparent conductive layer is in electrical contact with the second drain electrode through the contact hole.

In a further embodiment of the invention, the step of sequentially forming the first patterned conductive layer, the dielectric layer, the patterned semiconductor layer, the second patterned conductive layer and the second patterned transparent conductive layer on the front substrate includes the following steps: sequentially forming the first patterned conductive layer, the dielectric layer, the patterned semiconductor layer and the second patterned conductive layer on the front substrate; forming a protective layer with a contact hole and a trench covering the front substrate, in which the contact hole exposes the underneath second patterned conductive layer, the trench is configured to correspond to a part of the first patterned transparent conductive layer, and a part of the protective layer that corresponds to the location of the trench is thinned; and forming the second patterned transparent conductive layer on the protective layer so that the second patterned transparent conductive layer is in electrical contact with the second patterned conductive layer through the contact hole, the trench is covered by the second patterned transparent conductive layer, and a storage capacitor is formed between the first patterned transparent conductive layer and the second patterned transparent conductive layer.

The incident light enters the display panel from the front substrate and reaches the light sensing device before arriving at the display material layer. The reflective touch display panel and the manufacturing method thereof therefore have the merits of increasing the sensitivity of the light sensing device and being compatible with the original manufacturing process.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 is an exploded diagram of a reflective touch display panel according to one embodiment of the invention;

FIG. 2 is a perspective view of a light sensing device and a corresponding pixel structure on the front substrate;

FIG. 3 is a cross-sectional view of FIG. 2 taken along line A-A′, line B-B′ and line C-C′;

FIG. 4 is a flow chart of a manufacturing method of a reflective touch display panel according to one embodiment of the invention;

FIGS. 5A-5G are perspective views corresponding to the steps in FIG. 4; and

FIG. 6 is a perspective view of the of the reflective touch display panel in FIG. 5G with the protective layer having a trench.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

In the reflective touch display panel and the manufacturing method thereof, the light sensing device is disposed on the front substrate, and the light enters the display panel from the front substrate. Thus the light directly reaches the light sensing device, without passing through the reflective material layer first. The sensitivity of the light sensing device is increased and the product quality is improved.

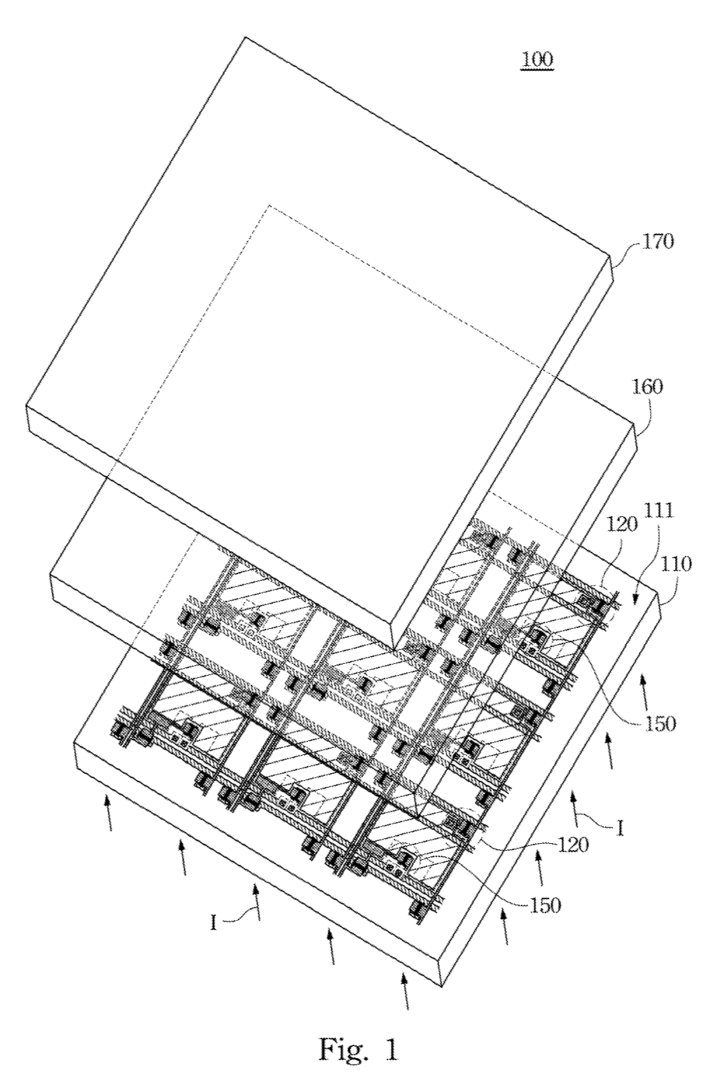

First, the detail description directs to a reflective touch display panel according to one embodiment of the invention. FIG. 1 is an exploded diagram of a reflective touch display panel according to one embodiment of the invention. The reflective touch display panel 100 includes a front substrate 110, a plurality of pixel structures 120, a plurality of light sensing devices 150, a reflective material layer 160 and a back substrate 170. The front substrate 110 has a inner surface 111, and an incident light I penetrates through the front substrate 110. The pixel structures 120 and the light sensing devices 150 are disposed on the inner surface 111 of the front substrate 110. The back substrate 170 is disposed on one side of the front substrate 110 in parallel. The reflective material layer 160 is disposed between the front substrate 110 and the back substrate 170 and is used for reflecting the incident light I penetrating through the front substrate 110.

In one embodiment, the reflective material layer 160 is directly sealed between the front substrate 110 and the back substrate 170, without using an adhesive layer 190. In another embodiment, the reflective touch display panel 100 optionally includes the adhesive layer 190. The adhesive layer 190 is disposed between the reflective material layer 160 and the front substrate 110 for adhering the reflective material layer 160 with the front substrate 110. The technology of the invention is not limited thereto; any other methods that are able to join the reflective material layer 160 with the front substrate 110 are applicable in the present invention. Practically, the reflective material layer 160 is exemplified by an electrophoretic display layer or a cholesterol liquid crystal layer. The applicable electrophoretic display layer includes, but is not limited to a layer of a micro-capsule array or a layer of a micro-cup array.

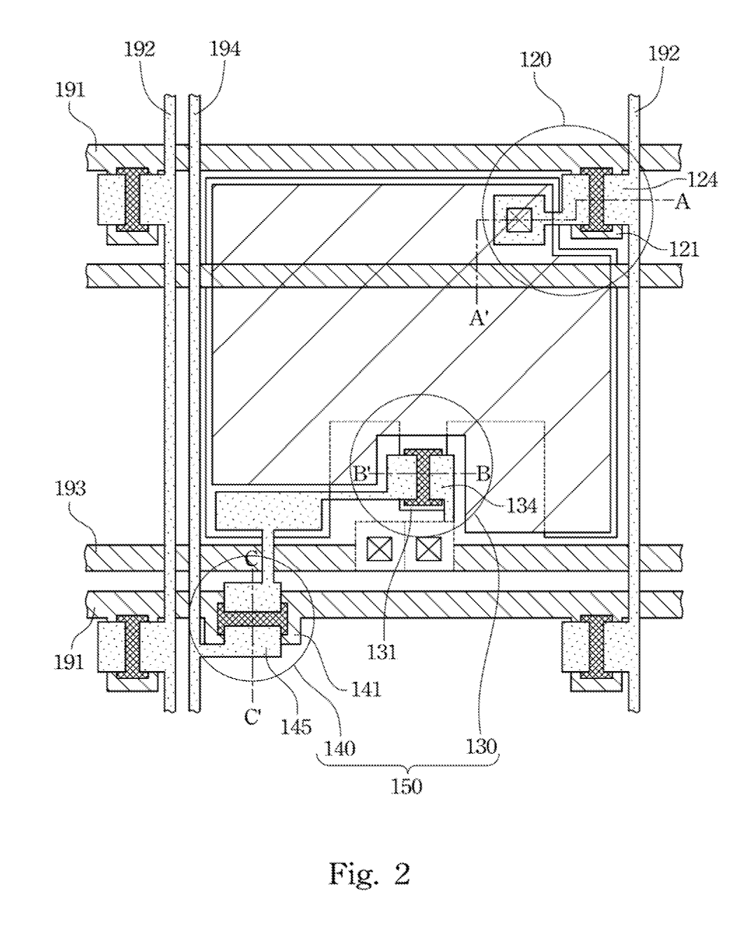

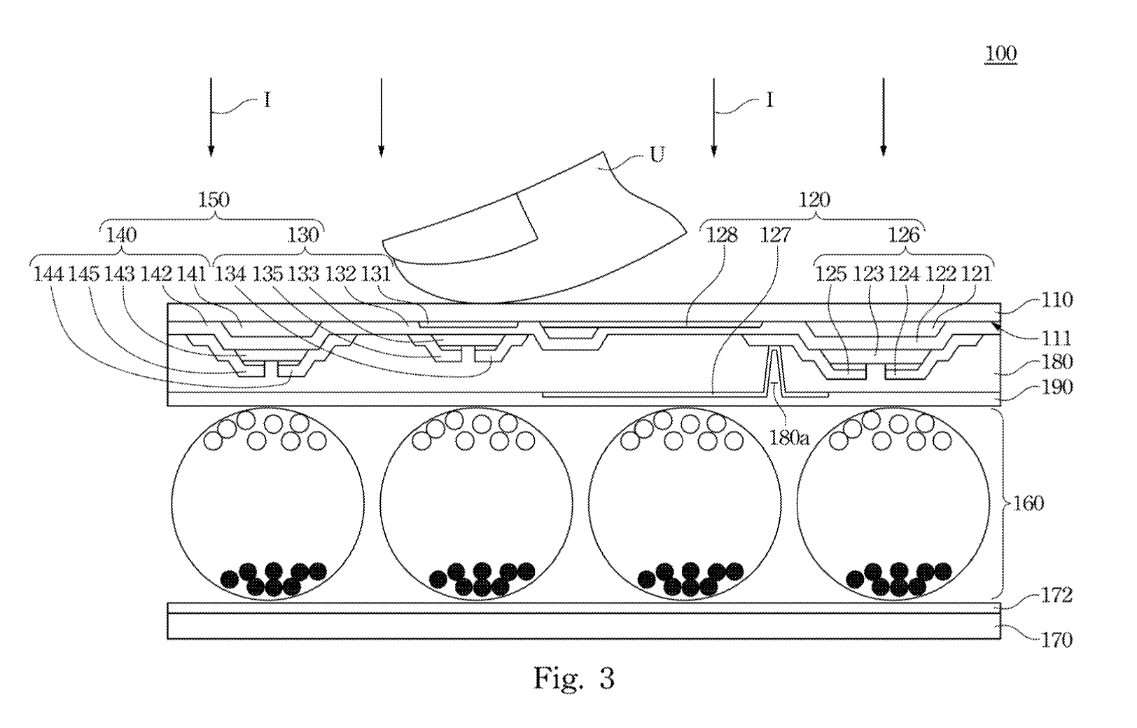

FIG. 2 is a perspective view of a light sensing device and a corresponding pixel structure on the front substrate. FIG. 3 is a cross-sectional view of FIG. 2 taken along line A-A′, line B-B′ and line C-C′. The light sensing device 150 includes a light sensing transistor 130 and a readout element 140. The light sensing transistor 130 includes a transparent gate electrode 131, a first gate dielectric layer 132, a first semiconductor layer 133, a first source electrode 134 and a first drain electrode 135. The transparent gate electrode 131 is disposed on the inner surface 111 of the front substrate 110. The first gate dielectric layer 132 and the first semiconductor layer 133 are sequentially disposed on the transparent gate. electrode 131. The first source electrode 134 and the first drain electrode 135 are respectively connected to the two sides of the first semiconductor layer 133. The readout element 140 is electrically connected to the light sensing transistor 130. In the present embodiment, the exemplary material of the transparent gate electrode 131 includes, but is not limited to, indium tin oxide, indium zinc oxide, aluminum zinc oxide or other suitable transparent conductive material.

Practically, when the incident light I penetrates through the front substrate 110 and reaches the light sensing transistor 130, the first semiconductor layer 133 is excited by the incident light I to form electron-hole pairs. As a result, an electrical pathway is formed between the first source electrode 134 and the first drain electrode 135, and a photo-current is generated accordingly. Therefore, the potential signal of the first source electrode 134 can be transmitted to the first drain electrode 135 via the electrical pathway formed within the first semiconductor layer 133. When the user U covers the light sensing transistor 130, e.g. placing his/hers finger over the light sensing transistor 130, the transparent gate electrode 131 of the light sensing transistor 130 is blocked from the incident light I. At this moment, the potential signal of the first source electrode 134 of the light sensing transistor 130 can not be transmitted to the first drain electrode 135. By this way, the reflective touch display panel 100 determines the touch location of the user U through the sensing mechanism of the light sensing transistor 130.

The pixel structure 120 of the present embodiment includes a thin film transistor 126 that includes a second gate electrode 121, a second gate dielectric layer 122, a second semiconductor layer 123, a second source electrode 124 and a second drain electrode 125. The second gate electrode 121 is disposed on the inner surface 111 of the front substrate 110. The second gate dielectric layer 122 and the second semiconductor layer 123 are sequentially disposed on the second gate electrode 121. The second source electrode 124 and the second drain electrode 125 are respectively connected to the two sides of the second semiconductor layer 123. In the present embodiment, the second gate electrode 121 and the transparent gate electrode 131 of the light sensing device 150 are made from different materials. For example, the transparent gate electrode 131 is made of indium tin oxide, and the second gate electrode 121 is made of an opaque conductive material, e.g. metal. The second gate electrode 121 uses the opaque conductive material to reduce the electrical interference, which is caused by the incident light I, to the second semiconductor layer 123.

The pixel structure 120 further includes a pixel electrode 127 and a capacitor lower electrode 128. The pixel electrode 127 is electrically connected to the second drain electrode 125 of the thin film transistor 126. The capacitor lower electrode 128 is made of a transparent material and is disposed on the inner surface 111 of the front substrate 110. In the present embodiment, the exemplary material of the capacitor lower electrode 128 includes indium tin oxide, indium zinc oxide, aluminum zinc oxide or other suitable transparent conductive material. The capacitor lower electrode 128 and the pixel electrode 127 form a transparent storage capacitor, which can avoid the aperture ratio of the reflective touch display panel 100 from being affected. The back substrate 170 has a common electrode 172 disposed thereon, and a voltage difference or an electric field is formed between each pixel electrode 127 and the common electrode 172. The reflection rate of the reflective material layer 160 is changed with the shifting of the voltage difference or the electric field, so as to control and manipulate the display effect. Besides that, the capacitor lower electrode 128 and the transparent gate 131 of the light sensing device 150 are connected to the same voltage level, thus simplifying the input of the signal lines. In yet another embodiment, the transparent gate electrode 131 of the light sensing device 150 may be connected to a scan line 191 or other signal lines, in which the content is known to a person skilled in the art and is not detailed here.

The readout element 140 of the light sensing device 150 includes a third gate electrode 141, a third gate dielectric layer 142, a third semiconductor layer 143, a third source electrode 144 and a third drain electrode 145. The third gate electrode 141 is disposed on the inner surface 111 of the front substrate 110. The third gate dielectric layer 142 and the third semiconductor layer 143 are sequentially disposed on the third gate electrode 141. The third source electrode 144 and the third drain electrode 145 are respectively connected to the two sides of the third semiconductor layer 143. In the present embodiment, the third gate electrode 141 and the second gate electrode 121 of the thin film transistor 126 are made from the same material, e.g. an opaque metal material.

The reflective touch display panel 100 further includes a protective layer 180 covering the pixel structure 120 and the light sensing device 150. The protective layer 180 is partially covered by the pixel electrode 127 of the pixel structure 120 and is provided with a contact hole 180a from which the underneath second drain electrode 125 is exposed. The pixel electrode 127 is electrically connected to the second drain electrode 125 via the contact hole 180a. In the present embodiment, the pixel electrode 127 of the pixel structure 120 and the capacitor lower electrode 128 are respectively located on two opposite sides of the protective layer 180, as depicted in FIG. 3.

More specifically, the reflective touch display panel 100 further includes a plurality of scan lines 191, a plurality of data lines 192, a plurality of signal input lines 193 and a plurality of signal output lines 194, as depicted in FIG. 2. The scan lines 191 are arranged in parallel, and each of the scan lines 191 is electrically connected to the second gate electrode 121 of the corresponding thin film transistor 126 and the third gate electrode 141 of the corresponding readout element 140 for providing scan signals. The data lines 192 are arranged in parallel and extend across the scan lines 191. In one embodiment, the data lines 192 are perpendicular to the scan lines 191. Each of the data lines 192 is electrically connected to the second source electrode 124 of the corresponding thin film transistor 126 for providing data signals. The signal input lines 193 are arranged in parallel and are parallel to the scan lines 191. Each of the signal input lines 193 is electrically connected to the first source electrode 134 of the corresponding light sensing transistor 130 for providing sensing signals. The signal output lines 194 are arranged in parallel and extend across the signal input lines 193. In one embodiment, the signal output lines 194 are perpendicular to the signal input lines 193. Each of the signal output lines 194 is electrically connected to the third drain electrode 145 of the corresponding readout element 140 for outputting the sensing signal to an external sensing circuit, so as to correctly diagnose the sensing signal.

In the reflective touch display panel 100 of the present embodiment, the light sensing device 150 and the pixel structure 120 are integrated on the front substrate 110. When the incident light I penetrates through the front substrate 110 and enters the reflective touch display panel 100, the light sensing device 150 is directly exposed to the incident light I. In this manner, the incident light I reaches the light sensing device 150 without passing through the reflective material layer 160, and the sensitivity of the light sensing device 150 is increased. By using the transparent gate electrode 131, the incident light I is able to pass through it and then reach the first semiconductor layer 133. Further more, the reflective touch display panel 100 uses the transparent capacitor lower electrode 128 and the pixel electrode 127 to form the transparent storage capacitor, so as to avoid the aperture ratio of the reflective touch display panel 100 being reduced.

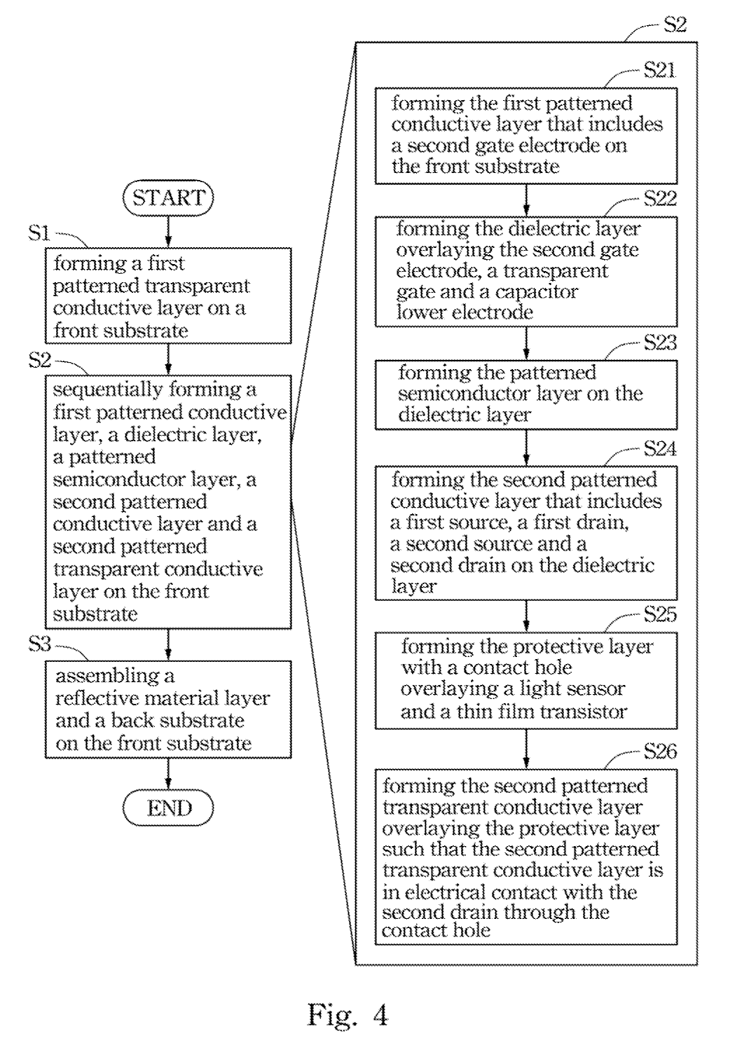

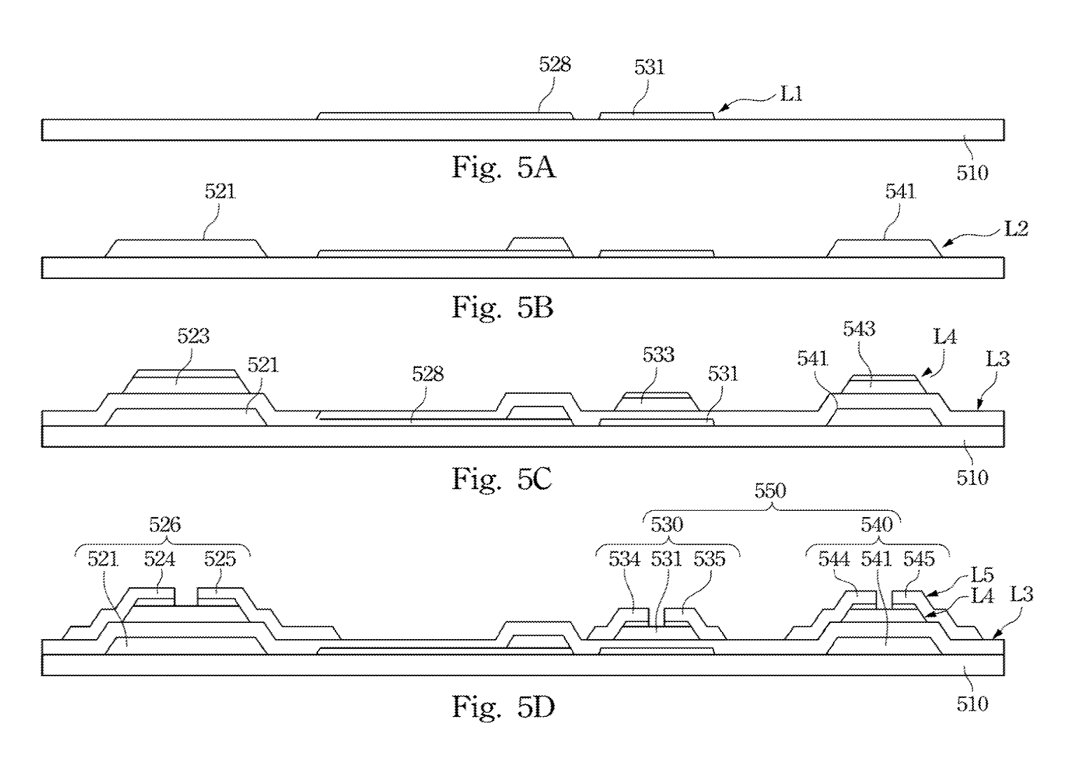

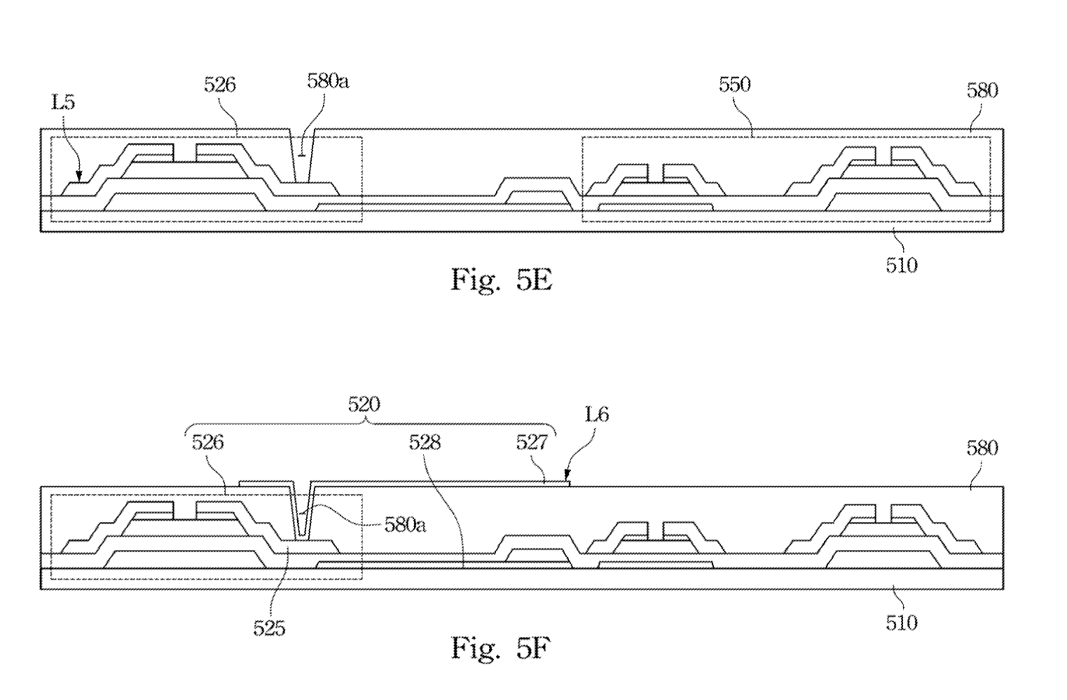

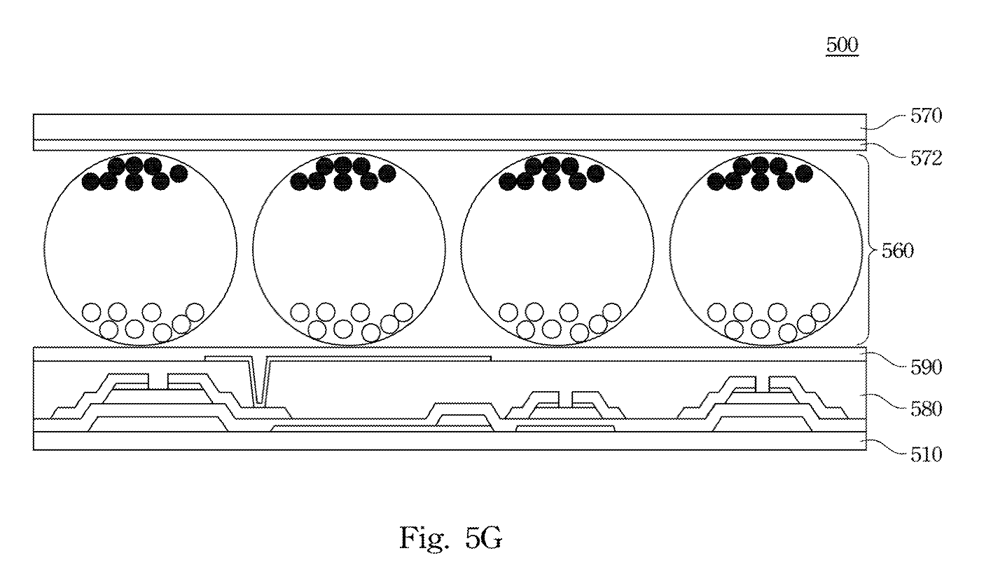

In the following elaboration, the detail description directs to a manufacturing method of the reflective touch display panel according to one embodiment of the invention. FIG. 4 is a flow chart of a manufacturing method of a reflective touch display panel according to one embodiment of the invention. FIGS. 5A-5G are perspective views corresponding to the steps in FIG. 4.

In step S1, a first patterned transparent conductive layer L1 is formed on the front substrate 510, as depicted in FIG. 5A. The first patterned transparent conductive layer L1 includes the transparent gate electrode 531 and the capacitor lower electrode 528. The transparent gate electrode 531 is used for forming the light sensing device, and the capacitor lower electrode 528 is used for forming the transparent storage capacitor of the pixel structure. In the present embodiment, the exemplary material of the first patterned transparent conductive layer L1 includes indium tin oxide, indium zinc oxide, aluminum zinc oxide or other transparent conductive material.

In step S2, the method moves on to the step of sequentially forming a first patterned conductive layer, a dielectric layer, a patterned semiconductor layer, a second patterned conductive layer and a second patterned transparent conductive layer on the front substrate 510. More specifically, step S2 of the present embodiment includes step S21 to step S26, which will be detailed in the following description.

In step S21, the first patterned conductive layer L2 is formed on the front substrate 510, as depicted in FIG. 5B. The first patterned conductive layer L2 includes a second gate electrode 521 and a third gate electrode 541. The second gate electrode 521 is used for forming a thin film transistor of the pixel structure, and the third gate electrode 541 is used for forming a readout element of the light sensing device.

In step S22 and step S23, the dielectric layer L3 is formed to overlay the second gate electrode 521, the transparent gate electrode 531, the capacitor lower electrode 528 and the third gate electrode 541, and the patterned semiconductor layer L4 is formed on the dielectric layer L3. The patterned semiconductor layer L4 includes a second semiconductor layer 523, a first semiconductor layer 533 and a third semiconductor layer 543, as depicted in FIG. 5C. The second semiconductor layer 523 is located on the second gate electrode 521. The first semiconductor layer 533 is located on the transparent gate electrode 531. The third semiconductor layer 543 is located on the third gate electrode 541.

In step S24, the manufacturing method according to the present embodiment then moves on to the step of forming the second patterned conductive layer L5 on the dielectric layer L3 and the patterned semiconductor layer L4. The second patterned conductive layer L5 includes a first source electrode 534, a first drain electrode 535, a second source electrode 524, a second drain electrode 525, a third source electrode 544 and a third drain electrode 545, as depicted in FIG. 5D. The first source electrode 534, the first drain electrode 535 and the transparent gate electrode 531 form the light sensing transistor 530 of the light sensing device. The second source electrode 524, the second drain electrode 525 and the second gate electrode 521 form the thin film transistor 526 of the pixel structure. The third source electrode 544, the third drain electrode 545 and the third gate electrode 541 for the readout element 540 of the light sensing device. The light sensing device 550 is therefore formed by the light sensing transistor 530 and the readout element 540.

In step S25, the step of forming a protective layer 580 with a contact hole 580a overlaying or covering the front substrate 510 is performed. The protective layer 580 covers the light sensing device 550 and the thin film transistor 526. A part of the second patterned conductive layer L5 is exposed from the contact hole 580a, as depicted in FIG. 5E.

In step S26, the step of forming the second patterned transparent conductive layer L6 on the protective layer 580 is performed. The second patterned transparent conductive layer L6 is in electrical contact with the second patterned conductive layer L5 via the contact hole 580a, as depicted in FIG. 5F. Furthermore, the second patterned transparent conductive layer L6 is regarded as a pixel electrode 527 and is in electrical contact with the second drain electrode 525 via the contact hole 580a. The pixel structure 520 is formed by the thin film transistor 526, the capacitor lower electrode 528 and the pixel electrode 527. The transparent storage capacitor of the pixel structure 520 is formed by the pixel electrode 527 and the capacitor lower electrode 528.

Afterwards, step S3 is performed in the manufacturing method of the present embodiment. A reflective material layer 560 and a back substrate 570 is assembled onto the front substrate 510 in a way that the reflective material layer 560 is located between the front substrate 510 and the back substrate 570, as depicted in FIG. 5G. The common electrode 572 is disposed on the back substrate 570, and a voltage difference or an electric field is formed between each the pixel electrode 527 and the common electrode 572. The reflection rate of the reflective material layer 560 is changed with the shifting of the voltage difference or the electric field, so as to control and manipulate the display effect. In one embodiment, the reflective material layer 560 is directly sealed between the front substrate 510 and the back substrate 570 without the necessity of using the adhesive layer 190. In another embodiment, step S3 further includes a step of adhering optionally. In this adhering step, an adhesive layer 590 is applied on the front substrate 510 for adhering the reflective material layer 560 to the front substrate 510.

After the above-mentioned step S1 to step S3 are finished, the reflective touch display panel 500 of one embodiment is completed, as shown in FIG. 5G.

In the reflective touch display panel 500, the pixel electrode 527 of the pixel structure 520 and capacitor lower electrode 528 (as shown in FIG. 5F) are respectively located on two opposite sides of the protective layer 580. Thus the capacitor lower electrode 528 and the pixel electrode 527 are separated by the protective layer 580. However, in yet another embodiment of the invention, a part of the protective layer 580 that located between the pixel electrode 527 and the capacitor lower electrode 528 is thinned or removed, so as to increase the capacitor characteristic and further improve the display quality of the reflective touch display panel 500.

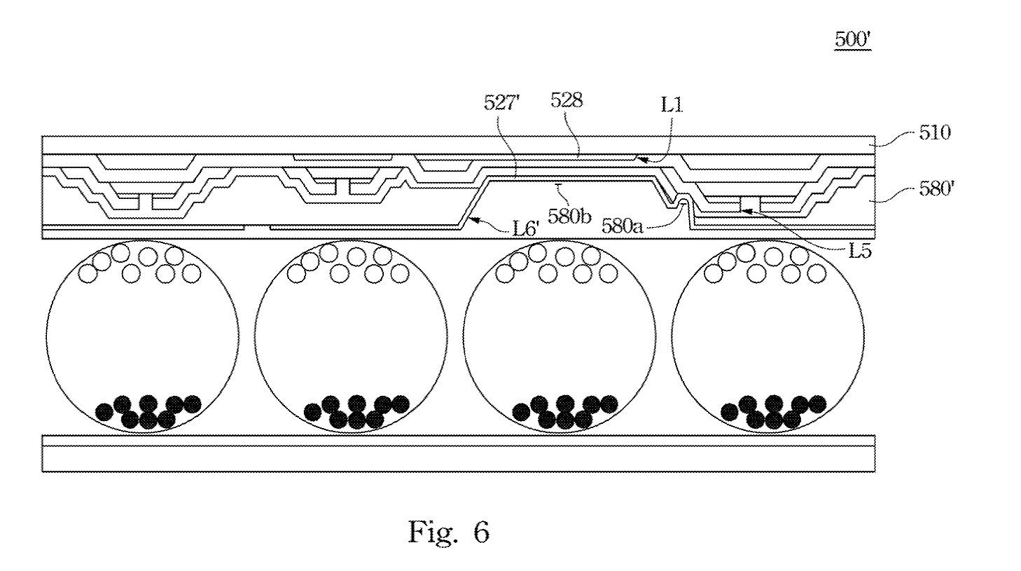

FIG. 6 is a perspective view of the of the reflective touch display panel in FIG. 5G with the protective layer having a trench. The reflective touch display panel 500′ is different from the above-mentioned reflective touch display panel 500 in that the protective layer 580′ of the reflective touch display panel 500′ has a trench 580b in addition to the contact hole 580a. The part of the protective layer 580′ below the trench 580b is thinned. In the step of forming the protective layer 580′ while manufacturing the reflective touch display panel 500′, for example, a half-tone mask is used for forming the contact hole 580a and the trench 580b through a photolithography and etching process. The trench is configured to correspond to a part of the first patterned transparent conductive layer L1. The second patterned transparent conductive layer L6′ is in electrical contact with the second patterned conductive layer L5 via the contact hole 580a. The trench 580b is overlaid with the second patterned transparent conductive layer L6′. In the present embodiment, the second patterned transparent conductive layer L6′ includes the pixel electrode 527′. The trench 580b is configured to correspond to the location of the capacitor lower electrode 528. Thus the overlapped pixel electrode 527′ and the capacitor lower electrode 528 form the transparent storage capacitor. The part of the protective layer 580′ between the pixel electrode 527′ and the capacitor lower electrode 528 are thinned, therefore enhancing the capacitance of the storage capacitor.

In the above-described reflective touch display panel and manufacturing method thereof of the embodiments of the invention, the light sensing device and the pixel structure are integrated on the front substrate. The incident light enters the display panel from the front substrate so that it can directly reach the light sensing transistor of the light sensing device. The sensitivity of the light sensing device is therefore improved. On the other hand, due to the reason that the light sensing transistor includes the transparent gate electrode and the lower electrode of the storage capacitor is transparent, the aperture ratio of the reflective touch display panel would not be affected.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A reflective touch display panel, comprising:
a front substrate having an inner surface for an incident light penetrating thereof;
a plurality of pixel structures disposed on the inner surface of the front substrate;
a plurality of light sensing devices disposed on the inner surface of the front substrate, and each of the light sensing devices comprises:
a light sensing transistor comprising a transparent gate electrode, a first gate dielectric layer, a first semiconductor layer, a first source electrode and a first drain electrode, wherein the transparent gate electrode is disposed on the inner surface of the front substrate, the first gate dielectric layer and the first semiconductor layer are sequentially disposed on the transparent gate electrode, and the first source electrode and the first drain electrode are respectively connected to two sides of the first semiconductor layer; and
a readout element electrically connected to the light sensing transistor;
a back substrate disposed opposite to the front substrate; and
a reflective material layer disposed between the front and the back substrates to reflect the incident light penetrating through the front substrate.

2. The reflective touch display panel of claim 1, wherein a material of the transparent gate electrode comprises indium tin oxide, indium zinc oxide or aluminum zinc oxide.

3. The reflective touch display panel of claim 1, wherein the reflective material layer is an electrophoretic display layer or a cholesteric liquid crystal layer.

4. The reflective touch display panel of claim 1, wherein each of the pixel structures comprises:
a thin film transistor comprising a second gate electrode, a second gate dielectric layer, a second semiconductor layer, a second source electrode and a second drain electrode, wherein the second gate electrode is disposed on the inner surface of the front substrate, the second gate dielectric layer and the second semiconductor layer are sequentially disposed on the second gate electrode, and the second source electrode and the second drain electrode are respectively connected to two sides of the second semiconductor layer;
a pixel electrode electrically connected to the second source electrode; and
a capacitor lower electrode, which is made of a transparent material, disposed on the inner surface of the front substrate, wherein the capacitor lower electrode and the pixel electrode form a transparent storage capacitor.

5. The reflective touch display panel of claim 4, wherein the transparent gate electrode and the capacitor lower electrode are connected to the same voltage level.

6. The reflective touch display panel of claim 4, wherein each of the readout elements comprises a third gate electrode, a third gate dielectric layer, a third semiconductor layer, a third source electrode and a third drain electrode, wherein the third gate electrode is disposed on the inner surface of the front substrate, the third gate dielectric layer and the third semiconductor layer are sequentially disposed on the third gate electrode, and the third source electrode and the third drain electrode are respectively connected to two sides of the third semiconductor layer.

7. The reflective touch display panel of claim 6 further comprising:
a plurality of scan lines, wherein each of the scan lines is electrically connected to the second gate electrode of the thin film transistor corresponding thereof and the third gate electrode of the readout element corresponding thereof;
a plurality of data lines crossing the scan lines, wherein each of the data lines is electrically connected to the second source electrode of the thin film transistor corresponding thereof;
a plurality of signal input lines being parallel to the scan lines, wherein each of the signal input lines is electrically connected to the first source electrode of the light sensing transistor corresponding thereof; and
a plurality of signal output lines crossing the signal input lines, wherein each of the signal output lines is electrically connected to the third drain electrode of the readout element corresponding thereof.

8. The reflective touch display panel of claim 4 further comprising:
a protective layer covering the pixel structures and the light sensing devices, wherein the protective layer is partially covered by the pixel electrode of each pixel structure and is provided with a contact hole through which the pixel electrode is in contact with the second drain electrode.

9. The reflective touch display panel of claim 8, wherein the pixel electrode and the capacitor lower electrode of each pixel structure are respectively located on two opposite sides of the protective layer.

10. The reflective touch display panel of claim 1, wherein the reflection rate of the reflective material layer is changed with the shifting of the voltage difference or the electric field applied to the reflective material layer.

11. A manufacturing method of a reflective touch display panel, comprising:
forming a first patterned transparent conductive layer on a front substrate, wherein the first patterned transparent conductive layer comprises a transparent gate electrode for forming a light sensing device and a capacitor lower electrode for forming a transparent storage capacitor of a pixel structure;
sequentially forming a first patterned conductive layer, a dielectric layer, a patterned semiconductor layer, a second patterned conductive layer and a second patterned transparent conductive layer on the front substrate for forming the light sensing device and the pixel structure; and
assembling a reflective material layer and a back substrate with the front substrate to seal the reflective material layer located between the front substrate and the back substrate.

12. The manufacturing method of claim 11, wherein a material of the first patterned transparent conductive layer comprises indium tin oxide, indium zinc oxide or aluminum zinc oxide.

13. The manufacturing method of claim 11, wherein the step of sequentially forming the first patterned conductive layer, the dielectric layer, the patterned semiconductor layer, the second patterned conductive layer and the second patterned transparent conductive layer on the front substrate comprises:
sequentially forming the first patterned conductive layer, the dielectric layer, the patterned semiconductor layer and the second patterned conductive layer on the front substrate;
forming a protective layer covering the front substrate, the protective layer having a contact hole above the second patterned conductive layer; and
forming the second patterned transparent conductive layer on the protective layer to electrically contact with the second patterned conductive layer through the contact hole.

14. The manufacturing method of claim 13, wherein the step of sequentially forming the first patterned conductive layer, the dielectric layer, the patterned semiconductor layer, the second patterned conductive layer and the second patterned transparent conductive layer on the front substrate further comprises:
forming the first patterned conductive layer comprising a second gate electrode on the front substrate;
forming the dielectric layer covering the second gate electrode, the transparent gate electrode and the capacitor lower electrode;
forming the patterned semiconductor layer on the dielectric layer;
forming the second patterned conductive layer comprising a first source electrode, a first drain electrode, a second source electrode and a second drain electrode on the dielectric layer, wherein the first source electrode, the first drain electrode and the transparent gate electrode form a light sensing transistor, and the second source electrode, the second drain electrode and the second gate electrode form a thin film transistor;
forming the protective layer with the contact hole covering the light sensing device and the thin film transistor; and
forming the second patterned transparent conductive layer on the protective layer to electrically contact with the second drain electrode through the contact hole.

15. The manufacturing method of claim 11, wherein the step of sequentially forming the first patterned conductive layer, the dielectric layer, the patterned semiconductor layer, the second patterned conductive layer and the second patterned transparent conductive layer on the front substrate comprises:
sequentially forming the first patterned conductive layer, the dielectric layer, the patterned semiconductor layer and the second patterned conductive layer on the front substrate;
forming a protective layer with a contact hole and a trench covering the front substrate, wherein the contact hole exposes the underneath second patterned conductive layer, the trench is configured to correspond to a part of the first patterned transparent conductive layer, and a part of the protective layer that corresponds to the location of the trench is thinned; and
forming the second patterned transparent conductive layer on the protective layer so that the second patterned transparent conductive layer is in electrical contact with the second patterned conductive layer through the contact hole, the trench is covered by the second patterned transparent conductive layer, and a storage capacitor is formed between the first patterned transparent conductive layer and the second patterned transparent conductive layer.

16. The manufacturing method of claim 11 further comprising:
applying an adhesive layer on the front substrate to join the reflective material layer.

17. The manufacturing method of claim 11, wherein the reflection rate of the reflective material layer is changed with the shifting of the voltage difference or the electric field applied to the reflective material layer.
